(19) United States
(12) Patent Application Publication
(10) Pub. No.: US 2007/0297267 A1
(43) Pub. Date: Dec. 27, 2007

(54) PORTABLE ELECTRONIC DEVICE AND COUPLING DEVICE FOR THE SAME

(76) Inventors: YOUNG-SOO HAN, ANYANG-SI (KR); SUNG-HYUN KA, GUNPO-SI (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/776,438

(22) Filed: Jul. 11, 2007

Related U.S. Application Data
(63) Continuation of application No. PCT/KR2006/000117, filed on Jan. 11, 2006.

(30) Foreign Application Priority Data
Jan. 11, 2005 (KR) 10-2005-002647

(51) Int. Cl. G11C 8/00

(52) U.S. Cl. 365/230.05

(57) ABSTRACT

Disclosed is a coupling device for coupling first and second units with each other in a portable apparatus having the first and second units and a rotation axis. The device included a first coupling member having a rotational coupling portion connected to the first unit so that the rotational coupling portion can be rotated about the rotation axis; and a second coupling member fixedly connected to the second unit. One member of the first and second coupling members includes a track portion extending along a movement axis and the other member includes a moving portion coupled with the track portion so that the moving portion can be slidably moved along the movement axis.

### CROSS-REFERENCE TO RELATED PATENT APPLICATIONS

This application is a continuation application under 35 U.S.C. §365(c) of International Application No. PCT/KR2006/000117, filed Jan. 11, 2006 designating the United States. International Application No. PCT/KR2006/000117 was published in English as WO2006/075871 A1 on Jul. 20, 2006. This application further claims the benefit of the earlier filing date under 35 U.S.C. §365(b) of Korean Patent Application No. 10-2005-002647 filed Jan. 11, 2005. This application incorporates herein by reference the International Application No. PCT/KR2006/000117 including the International Publication No. WO2006/075871 A1 and the Korean Patent Application No. 10-2005-002647 in their entirety.

### BACKGROUND

1. Field

The present disclosure relates to a portable apparatus, and more particularly, to a portable electric or electronic apparatus, such as a mobile telephone, a PDA or a portable computer.

2. Discussion of the Related Technology

A portable apparatus such as a portable telephone comprises two units that are provided with a liquid crystal display and a keypad, respectively. A user carries the portable apparatus with the two units completely folded against each other. While the portable apparatus is in use, the two units are moved relatively with respect to each other to increase the area of the portable apparatus. Such portable apparatuses are divided into a folder type and a slide type according to the mode of relative movement by the two units with respect to each other. Two units of the folder type are coupled with each other so that the two units can be rotated to be folded or unfolded with respect to each other, while two units of the slide type are coupled with each other so that the two units can be slidably moved with respect to each other. Since an exemplary portable apparatus has two units that are coupled with each other to be operated only in a single mode selected from the folder type and the slide type, the use of the portable apparatus may be limited.

The foregoing discussion is to provide general background information, and does not constitute an admission of prior art.

### SUMMARY

One aspect of the invention provides a portable electronic device, comprising: a first panel comprising a first surface; a second panel comprising a second surface, wherein the first surface and the second surface are of substantially the same size such that the first and second surfaces can substantially entirely overlap with each other; a connector interconnecting the first panel and the second panel, wherein the connector is configured to enable the first panel to rotate relative to the second panel about an axis and further configured to enable the first panel to slide relative to the second panel along the axis; wherein the device is configured to form a first folded configuration in which the first surface faces the second surface, and the first surface substantially entirely overlaps with the second surface; wherein the device is further configured to form a second folded configuration in which the first surface faces the second surface, and the first and second panels are linearly offset along the axis from the first folded configuration such that the first surface partially overlaps with the second surface; wherein the device is further configured to form a first unfolded configuration in which the first and second panels are angularly offset about the axis from the first folded configuration such that the first and second surfaces do not face each other; and wherein the device is further configured to form a second unfolded configuration in which the first and second panels are angularly offset about the axis from the second folded configuration such that the first and second surfaces do not face each other.

In the foregoing device, in the first unfolded configuration, the connector may be interposed between the first and second panels when viewed, from a point that is away from the device, in a direction perpendicular to the first surface. The connector may be further configured to enable the first panel to spontaneously slide relative to the second panel along the axis to either the first or second folded configuration when the device is in a configuration that is between the first folded and second folded configurations. The connector may be further configured to enable the first panel to spontaneously slide relative to the second panel along the axis to either the first or second unfolded configuration when the device is in a configuration that is between the first unfolded and second unfolded configurations.

Still in the foregoing device, the connector may comprise a guide extending along the axis and non-slidably coupled to the second panel, wherein the connector may further comprise a slider slidably engaged with the guide and non-slidably coupled to the first panel. The guide may comprise a first magnet and a second magnet spaced from each other along the axis, wherein the slider may comprise a third magnet and a fourth magnet arranged between the first and second magnets along the axis. The first magnet and the third magnet may be configured to attract each other, and wherein the second magnet and the fourth magnet may be configured to attract each other. The device may be configured to form a third folded configuration that is between the first and second folded configurations, wherein an attractive force between the first and third magnets may be greater than an attractive force between the second and fourth magnets when the device is in a configuration that is between the first folded and third folded configurations. The guide may further comprise a fifth magnet, wherein the slider may further comprise a sixth magnet, wherein the fifth magnet and the sixth magnet may be arranged such that a repulsive force can be exerted therebetween in a configuration where the device is slightly off the third folded configuration.

Another aspect of the invention provides a method of operating a portable electronic device, the method comprising: providing the foregoing portable electronic device; rotating the first panel relative to the second panel about the axis; and sliding the first panel relative to the second panel along the axis.

In the foregoing method, sliding the first panel relative to the second panel along the axis may change a configuration of the device between the first and second folded configurations. Sliding the first panel relative to the second panel along the axis may change a configuration of the device between the first and second unfolded configurations. Rotating the first panel relative to the second panel about the axis may change a configuration of the device between the first folded configuration and the first unfolded configuration. Rotating the first panel relative to the second panel about the axis may change a configuration of the device between the second folded configuration and the second unfolded configuration. The connector may enable the first panel to spontaneously slide relative to the second panel along the axis to either the first or second folded configuration when the device is in a configuration that is between the first folded and second folded configurations. The connector may enable the first panel to spontaneously slide relative to the second panel along the axis to either the first or second unfolded configuration when the device is in a configuration that is between the first unfolded and second unfolded configurations.

Yet another aspect of the invention provides a portable electronic device, comprising: a first panel comprising a first surface; a second panel comprising a second surface, wherein the first surface and the second surface are of substantially the same size; a connector interconnecting the first panel and the second panel, wherein the connector is configured to rotatably connect the first panel and the second panel relative to each other about an axis and further configured to slidably connect the first panel and the second panel relative to each other along the axis; wherein the device is configured to form a first folded configuration in which the first surface faces the second surface, and the first surface substantially entirely overlaps with the second surface; wherein the device is further configured to form a second folded configuration in which the first surface faces the second surface, and the first and second panels are linearly offset along the axis from the first folded configuration such that the first surface partially overlaps with the second surface; wherein the device is further configured to form a first unfolded configuration in which the first and second panels are angularly offset about the axis from the first folded configuration such that the first and second surfaces do not face each other; and wherein the first panel comprises a display screen on the first surface, wherein the connector does not overlap with the display screen in the first folded configuration when viewed, from a point that is away from the first surface, in a direction perpendicular to the first surface.

In the foregoing device, the connector is interposed between the first and second panels when viewed, from a point that is away from the device, in a direction perpendicular to the first surface. The first panel may comprise a third surface facing away from the second surface in the first folded configuration, wherein the first panel comprises a second display screen on the third surface, wherein the second display screen does not overlap with the connector in the first folded configuration when viewed, from the point that away from the first surface, in a direction perpendicular to the first surface. The second panel may comprises an array of buttons on the second surface, wherein the array of buttons does not overlap with the connector in the first folded configuration when viewed, from a point that is away from the second surface, in a direction perpendicular to the second surface. The connector may comprise a hinge configured to enable the first panel to rotate relative to the connector about the axis. The connector may comprise a guide extending along the axis and non-slidably coupled to the first panel, wherein the connector may further comprise a slider slidably engaged with the guide and non-slidably coupled to the second panel.

An aspect of the present invention provides a portable apparatus having two units, which can be selectively used in either a slide mode or a folder mode, and a coupling device for coupling the two units of the portable apparatus.

An aspect of the present invention provides a coupling device for coupling first and second units with each other in a portable apparatus having the first and second units and a rotation axis, comprising a first coupling member having a rotational coupling portion connected to the first unit so that the rotational coupling portion can be rotated about the rotation axis; and a second coupling member fixedly connected to the second unit, wherein one member of the first and second coupling members includes a track portion extending along a movement axis, and the other member includes a moving portion coupled with the track portion so that the moving portion can be slidably moved along the movement axis.

The coupling device may further comprise a first resilient member for applying a force to the moving portion so that the moving portion can be moved toward one side along the movement axis with respect, to the track portion, and a releasable stopper for limiting the movement of the moving portion with respect to the track portion.

In the coupling device, the stopper may include a locking member received in one of the first and second coupling members so that the locking member can be moved in a direction substantially perpendicular to the movement axis; a locking hole provided in the other member so that the locking member can be caught in the locking hole; and a second resilient member for urging the locking member toward one side so as to maintain a state where the locking member is caught in the locking hole. In the coupling device, the stopper may further include a button member provided to move the locking member.

In the coupling device, the track portion-including coupling member of the first and second coupling members may include first two magnets positioned at both ends of a slide movement region of the moving portion, while the moving portion-including coupling member of the first and second coupling members may include second two magnets positioned to face the first two magnets. Magnetic poles of the first and second magnets facing each other may be arranged such that an attractive force is exerted therebetween.

The coupling device may further comprise a third magnet fixed together with the two first magnets and positioned between the two first magnets and a fourth magnet fixed together with the two second magnets and positioned between the two second magnets. Magnetic poles of the third and fourth magnets may be arranged such that a repulsive force is exerted when the fourth magnet is positioned between the third magnet member and the first magnet member.

One of the first and second coupling members may be provided with a rack extending along the movement axis, and the other may be provided with a pinion cooperating with the rack and a driving motor for rotating the pinion. The pinion and the driving motor may be connected to the other member such that they can move together. In the coupling device, the rotation axis and the movement axis may be substantially parallel to each other.

Another aspect of the present invention provides a portable apparatus comprising first and second units coupled by means of the aforementioned coupling device. The portable apparatus may further comprise a hinge device for rotatably coupling the first unit with the rotational coupling member of the coupling device.

A further aspect of the present invention provides a method of using a portable apparatus including two units and a coupling device for coupling the two units, wherein the coupling device includes two coupling members connected respectively to the two units so that the two coupling members can be slidably moved to each other along a movement axis, and one of the two units is connected to the coupling device so that the one of the two units can be rotated about a rotation axis. The method comprises the steps of rotating one of the two units about the rotation axis with respect to the other of the two units; and slidably moving one of the two units along the movement axis with respect to the other of the two units.

### BRIEF DESCRIPTION OF THE DRAWINGS

FIG. 1 is a perspective view of a portable apparatus according to one embodiment of the present invention.

FIGS. 2(a) and (b) are exploded perspective views of the portable apparatus shown in FIG. 1.

FIGS. 3(a) to (c) are perspective views of a coupling device provided in the portable apparatus shown in FIG. 1.

FIGS. 4(a) and (b) are exploded perspective views of the coupling device shown in FIG. 3.

FIGS. 5(a) to (d) are views showing operational states of the portable apparatus shown in FIG. 1.

FIG. 6 is an exploded perspective view of another embodiment of the coupling device provided in the portable apparatus shown in FIG. 1.

FIGS. 7(a) to (d) are views showing operational states of the coupling device shown in FIG. 6.

FIG. 8 is an exploded perspective view of a further embodiment of the coupling device provided in the portable apparatus shown in FIG. 1.

### DETAILED DESCRIPTION OF EMBODIMENTS

Hereinafter, embodiments of the present invention will be described in detail with reference to the accompanying drawings.

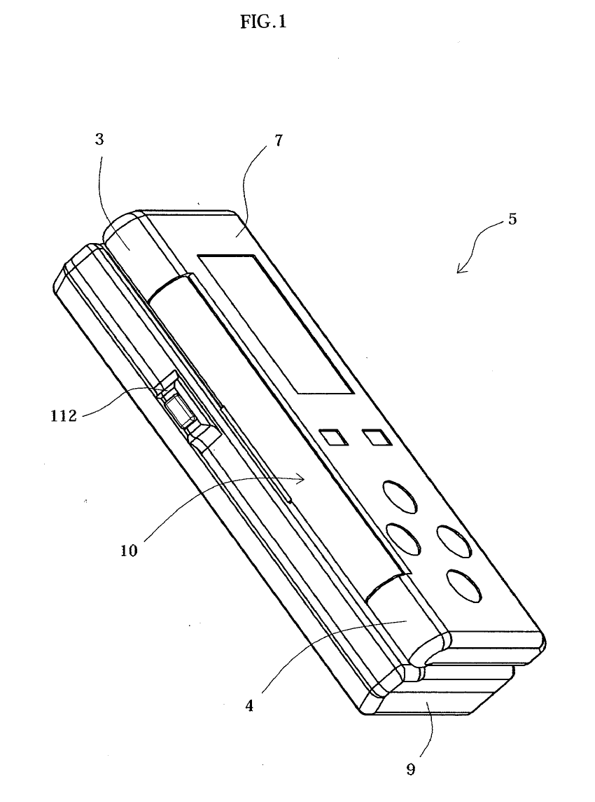

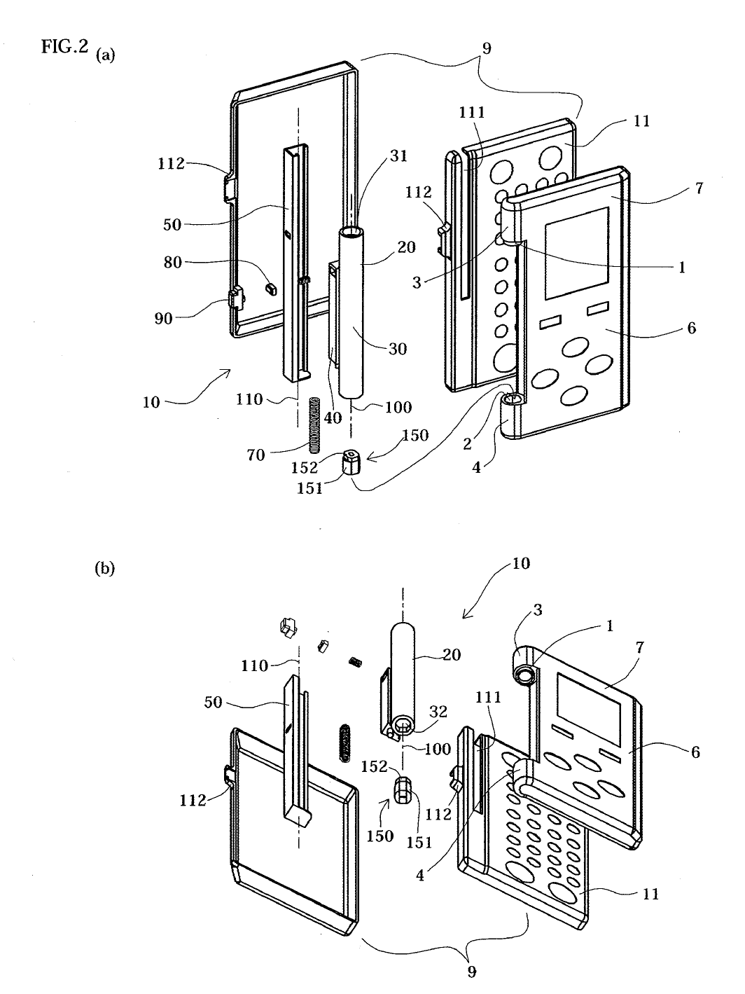

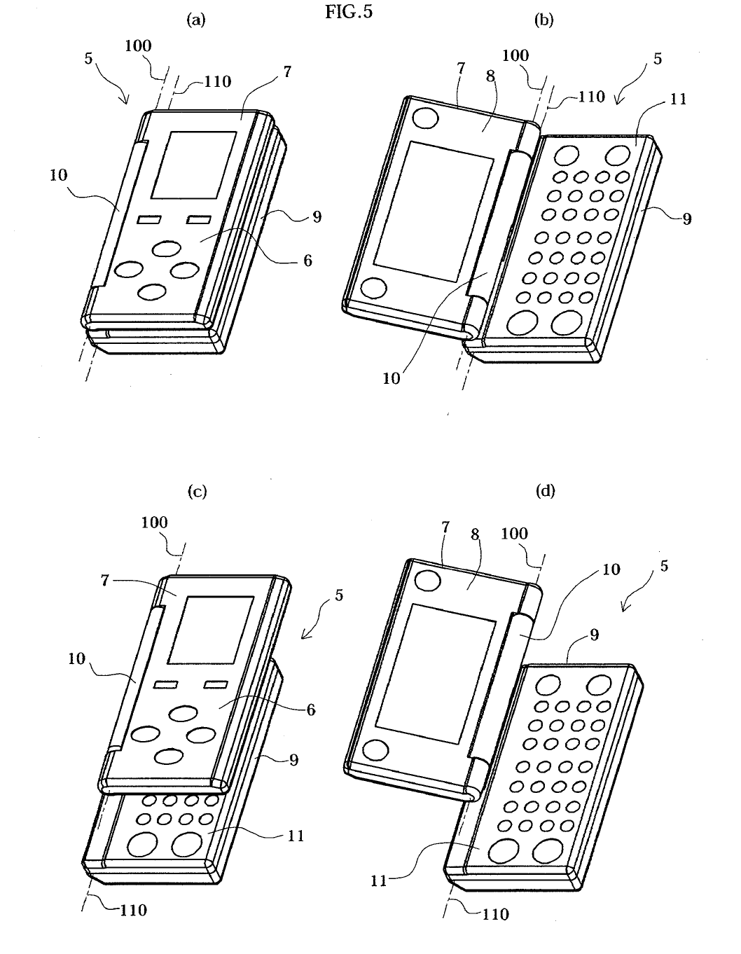

Referring to FIG. 1, a portable apparatus 5 (e.g., a portable telephone) comprises a first unit or panel 7 and a second unit or panel 9, which are in the form of plates and can be superimposed on each other. The first unit 7 and the second unit 9 are coupled with each other by means of a coupling device 10. Referring to FIGS. 2 and 5, a first surface 6 of the first unit 7 is provided with a liquid crystal display and a keypad, while a second surface 8 formed at a side opposite to the first surface 6 is provided with a liquid crystal display. A third surface 11 of the second unit 9 is provided with a keypad.

When the first and second units 7 and 9 are completely superimposed on each other, the second surface 8 of the first unit 7 and the third surface 11 of the second unit 9 are in face-to-face contact with each other. The first unit 7 is coupled with a first coupling member 20 of the coupling device 10, which will be described later, by means of a hinge device 150 so that they can be relatively rotated about a rotation axis 100. At this time, although the hinge device 150 may be the hinge device constructed as disclosed in Korean Patent No. 266516, the present invention is not limited thereto.

The first unit 7 is provided with first and second protrusions 3 and 4 that protrude to be coupled with both ends of a coupling portion 30 of the first coupling member 20 of the coupling device 10, which will be described later. The first and second protrusions 3 and 4 have two surfaces facing each other, wherein one surface of the two surfaces formed in the first protrusion 3 is provided with a coupling post 1, while the other surface formed in the second protrusion 4 is provided with a mounting hole 2. The coupling post 1 takes the shape of a cylinder be inserted into a first coupling hole 31 of the coupling portion 30 of the first coupling member 20, which will be described later, so that the coupling post 1 can be freely rotated in the first coupling hole 31. A housing 151 of the hinge device 150 is inserted into the mounting hole 2.

A second coupling member 50 of the coupling device 10, which will be described later, is fixedly mounted at a side of the interior of the second unit 9. An opening 11 that communicates with the interior of the second unit 9 is provided at a side of the third surface 11 of the second unit 9. A connection portion 21 of the first coupling member 20 of the coupling device 10, which will be described later, passes the exterior and interior of the second unit 9 through the opening portion 111. The opening portion 111 of the second unit 9 extends lengthwise along a movement axis 110 that is substantially parallel to the rotation axis 100, so that the first coupling member 20 of the coupling device 10 can be slidably moved along the movement axis 110 with respect to the second coupling member 50. The second unit 9 is provided with a receiving portion 112 in which a manipulation button 90 of the coupling device 10, which will be described later, is to be received. The receiving portion 112 is configured such that the manipulation button 90 does not come out of the second unit 9 while one end of the manipulation button 90 protrudes outside the second unit 9, and that the manipulation button 90 can be moved in a direction substantially perpendicular to the movement axis 110.

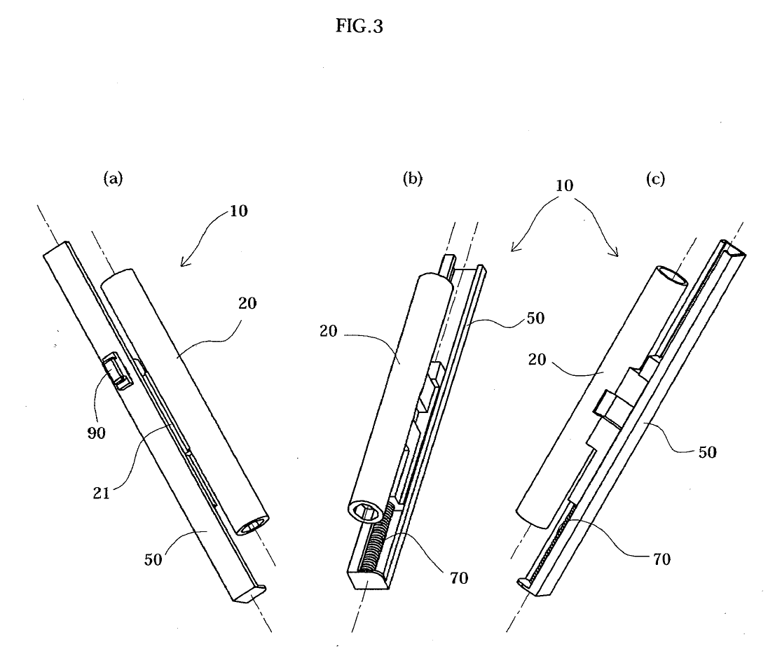

Referring to FIGS. 2 to 4, the coupling device 10 comprises the first coupling member 20, the second coupling member 50, a first resilient member 70, the manipulation button 90, and a stopper serving as a movement-limiting means. The first coupling member 20 comprises the coupling portion 30 that is coupled with the first unit 7 and relatively rotated about the rotation axis 100, a moving portion 40 that is coupled with the second coupling member 50 and slidably moved along the movement axis 110, and the connection portion 21 for connecting the coupling portion 30 to the moving portion 40. The coupling portion 30 takes the shape of a cylinder extending along the rotation axis 100 and is provided at both ends thereof with first and second coupling holes 31 and 32, respectively. The first coupling hole 31 is a circular hole, and the coupling post 1 of the first unit 7 is inserted into the first coupling hole 31 so that the coupling post 1 can be freely rotated therein.

A connection member 152 of the hinge device 150 is inserted into the second coupling hole 32 so that the coupling portion 30 and the connection member 152 of the hinge device 150 can be rotated together about the rotation axis 100. The moving portion 40 takes the shape of a rod extending along the movement axis 110 and is slidably inserted into a track portion 51 of the second coupling member 50. The moving portion 40 is provided at a side thereof with a receiving slot 42 in which a locking member 80 and a second resilient member 82 that will be described later are received. The locking member 80 received in the receiving slot 42 can be moved in a direction substantially perpendicular to the movement axis 110. The connection portion 21 passes through the opening 111 of the second unit 9, thereby connecting the coupling portion 30 and the moving portion 40 which are positioned outside and inside of the second unit 9, respectively.

The second coupling member 50 comprises the track portion 51 which extends lengthwise along the movement axis 110 and into which the moving portion 40 of the first coupling member 20 can be inserted to be slidably moved along the movement axis 110. A side surface of the second coupling member 50 is provided with a locking hole 54 for communicating the exterior of the second coupling member 50 with the track portion 51 inside the second coupling member 50. The locking member 80 can be inserted into and caught in the locking hole 54. The second coupling member 50 is fixed inside the second unit 9. The first resilient member 70 is a compression coil spring of which one end is in contact with the moving portion 40 of the first coupling member 20 while the other end is in contact with an end wall 52 of the second coupling member 50. The first resilient member 70 urges the first coupling member 20 to be moved toward one side along the movement axis 110 with respect to the second coupling member 50, wherein the moving direction of the first coupling member 20 is a direction in which the first unit 7 is moved such that the third surface 11 of the second unit 9 can be exposed.

The stopper comprises the locking member 80, the second resilient member 82, the receiving slot 42 formed in the first coupling member 20, and the locking hole 54 formed in the second coupling member 50. The locking member 80 and the second resilient member 82 are received in the receiving slot 42 of the first coupling member 20. The locking member 80 can be moved in the receiving slot 42 along a direction substantially perpendicular to the movement axis 110. The second resilient member 82 is a compression coil spring that urges the locking member 80 outward of the receiving slot 42. The locking member 80 can be inserted into and caught in the locking hole 54. When the locking member 80 is caught in the locking hole 54, the relative slide movement between the first coupling member 20 and the second coupling member 50 is limited. When the manipulation button 90 is pushed down when the locking member 80 is caught in the locking hole 54, the manipulation button 90 pushes the locking member 80 so that the locking member 80 can come out from the locking hole 54. Then, the urging force of the first resilient member 70 causes the first coupling member 20 to be automatically moved with respect to the second coupling member 50 along the movement axis 110.

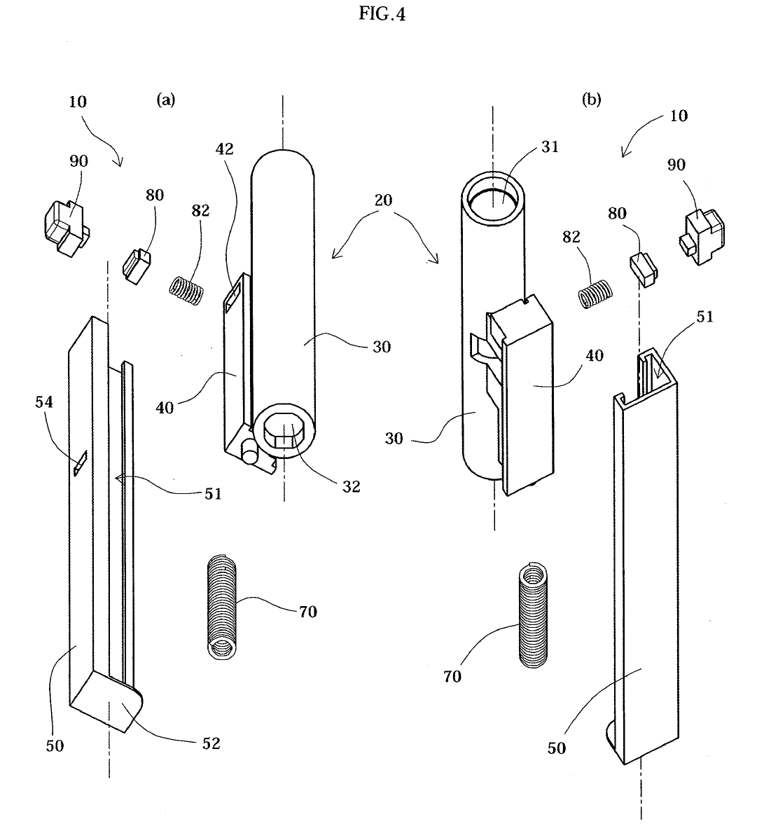

FIGS. 5(a) to (d) show usage examples of the portable apparatus shown in FIG. 1. FIGS. 5(a) and (b) show states where the locking member 80 (see FIG. 14) of the coupling device 10 is inserted into the locking hole 54 (see FIG. 4), wherein FIG. 5(a) shows a state where the two units 7 and 9 of the portable apparatus 5 are completely superimposed on each other so that the portable apparatus can be folded, while FIG. 5(b) shows a state where the first and second units 7 and 9 of the portable apparatus 5 are relatively rotated about the rotation axis 100 from the state shown in FIG. 5(a) so that the portable apparatus can be unfolded.

When the manipulation button 90 (see FIG. 4) is pushed down at the state shown in FIG. 5(a), the locking member 80 (see FIG. 4) comes out from the locking hole 54 (see FIG. 4) so that the first resilient member 70 (see FIG. 4) can cause the first coupling member 20 (see FIG. 4) to be automatically moved toward one side thereof with respect to the second coupling member 50 (see FIG. 4) along the movement axis 110, thereby causing the portable apparatus to be in the state shown in FIG. 5(c). Further, when the manipulation button 90 (see FIG. 4) is pushed down in the state shown in FIG. 5(b), the locking member 80 (see FIG. 4) comes out from the locking hole 54 (see FIG. 4) so that the first resilient member 70 (see FIG. 4) can cause the first coupling member 20 (see FIG. 4) to be automatically moved toward one side thereof with respect to the second coupling member 50 (see FIG. 4) along the movement axis 110, thereby causing the portable apparatus to be in the state shown in FIG. 5(d).

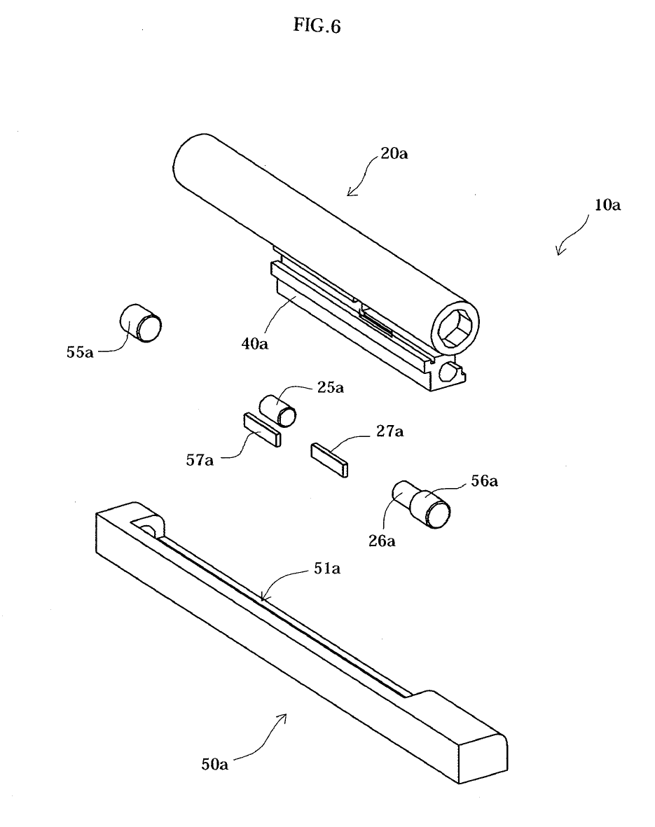

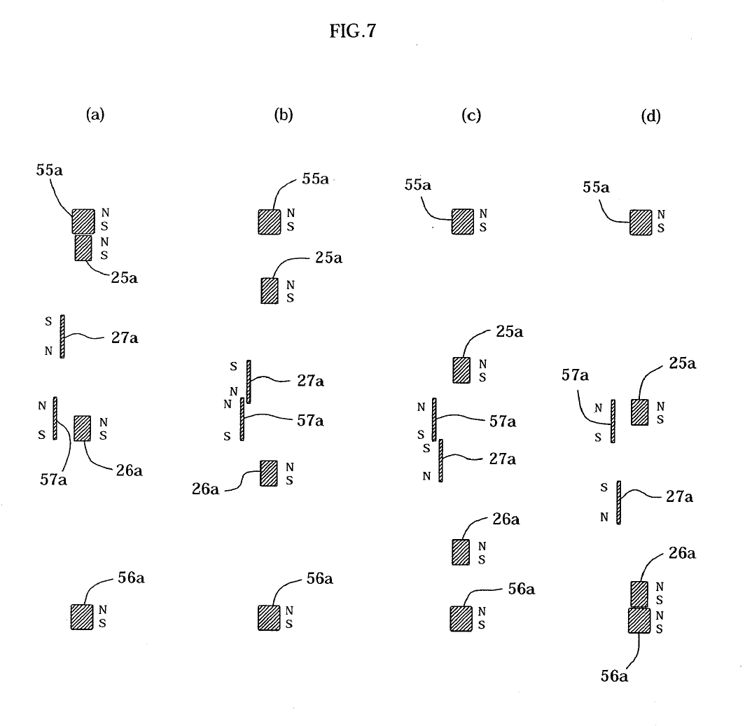

Referring to FIG. 6, a coupling device 10a comprises a first coupling member 20a and a second coupling member 50a. The second coupling member 50a comprises a first A magnet 55a, a first B magnet 56a, and a third magnet 57a. Referring to FIG. 7 together with FIG. 6, the first A magnet 55a and the first B magnet 56a are mounted at both ends of a track portion 51a of the second coupling member 50a. The third magnet 57a is mounted on the track portion 51a at a middle position between the first A magnet 55a and the first B magnet 56a.

A moving portion 40a of the first coupling member 20a comprises a second A magnet 25a, a second B magnet 26a and a fourth magnet 27a. The second A magnet 25a and the second B magnet 26a are mounted at both ends of the moving portion 40a of the first coupling member 20a. The second A magnet 25a corresponds to the first A magnet 55a of the second coupling member 50a, and their magnetic poles are arranged to apply an attractive force to each other. The second B magnet 26a corresponds to the first B magnet 56a of the second coupling member 50a, and their magnetic poles are arranged to apply an attractive force to each other. The fourth magnet 27a is mounted at a middle position between the second A magnet 25a and the second B magnet 26a and cooperates with the third magnet 57a of the second coupling member 50a.

When the fourth magnet 27a is positioned between the third magnet 57a and the first A magnet 55a (as shown in FIGS. 7(a) and (b)) and the fourth magnet 27a is positioned between third magnet 57a and first B magnet 56a (as shown in FIGS. 7(c) and (d)), the magnetic poles of the third and fourth magnets 57a and 27a are arranged to apply a repulsive force to each other. FIG. 7 shows arrangement examples of the magnetic poles of the respective magnets. Since the other constitutions are substantially identical with those of the coupling device 10 shown in FIG. 4, descriptions thereof will be omitted.

Now, the operation of the coupling device 10a shown in FIG. 6 will be described in detail with reference to FIG. 7. Referring to FIG. 7(a), the second A magnet 25a of the first coupling member 20a (see FIG. 6) is attached to the first A magnet 55a of the second coupling member 50a (see FIG. 6). At this time, the fourth magnet 27a is positioned at a middle position between the third magnet 57a and the first A magnet 55a.

When an external force is applied to the first unit 7 in this state so that the second A magnet 25a can be separated from the first A magnet 55a and slightly moved, the state shown in FIG. 7(b) is obtained. When the external force is removed in this state, the attractive force between the first A magnet 55a and the second A magnet 25a and the repulsive force between the third magnet 57a and the fourth magnet 27a cause the state to be returned to that shown in FIG. 7(a). When an external force continues to be applied to the first unit 7 in the state shown in FIG. 7(b) so that the fourth magnet 27a can pass by the third magnet 57a, the state shown in FIG. 7(c) is obtained. When the external force is removed in this state, the attractive force between the first B magnet 56a and the second B magnet 26a and the repulsive force between the third magnet 57a and the fourth magnet 27a cause the state to automatically become that shown in FIG. 7(d).

Referring to FIG. 7(d), the second B magnet 26a has been attached to the first B magnet 56a. The portable apparatus comprising two units coupled with each other by means of the coupling device 10b, which functions as described above, can be operated as shown in FIG. 5.

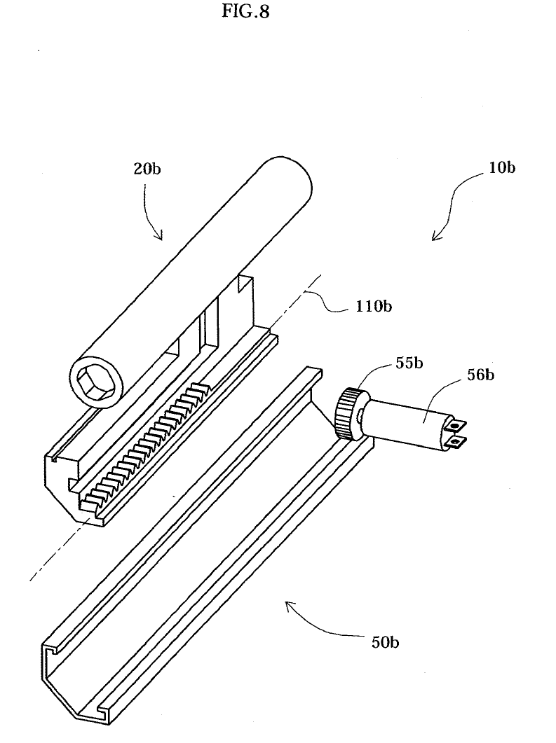

Referring to FIG. 8, the coupling device 10b comprises a first coupling member 20b and a second coupling member 50b. The first coupling member 20b is provided with a rack 22b extending along a movement axis 110b. The second coupling member 50b is provided with a pinion 55b cooperating with the rack 22b of the first coupling member 20b, and a driving motor 56b for rotating the pinion 55b. Since the other constitutions are substantially identical with those of the coupling device 10 shown in FIG. 4, descriptions thereof will be omitted. The portable apparatus comprising the two units coupled with each other by means of the coupling device 10b, which functions as described above, can be operated as shown in FIG. 5.

Although the coupling device has been described as being mounted in a portable telephone in this embodiment, the present invention is not limited thereto. The coupling device may be used in an apparatus (e.g., a PDA, a portable computer, etc) including two units coupled with each other in addition to the portable telephone.

Although embodiments of the present invention has been illustrated and described, it can be understood by those skilled in the art that various modifications and changes can be made thereto without departing from the scope and spirit of the present invention and such various modifications and changes fall within the scope of the present invention.

What is claimed is:

1. A portable electronic device, comprising:
a first panel comprising a first surface;
a second panel comprising a second surface, wherein the first surface and the second surface are of substantially the same size such that the first and second surfaces can substantially entirely overlap with each other;
a connector interconnecting the first panel and the second panel, wherein the connector is configured to enable the first panel to rotate relative to the second panel about an axis and further configured to enable the first panel to slide relative to the second panel along the axis;
wherein the device is configured to form a first folded configuration in which the first surface faces the second surface and the first surface substantially entirely overlaps with the second surface;
wherein the device is further configured to form a second folded configuration in which the first surface faces the second surface, and the first and second panels are linearly offset along the axis from the first folded configuration such that the first surface partially overlaps with the second surface;
wherein the device is further configured to form a first unfolded configuration in which the first and second panels are angularly offset about the axis from the first folded configuration such that the first and second surfaces do not face each other; and
wherein the device is further configured to form a second unfolded configuration in which the first and second panels are angularly offset about the axis from the second folded configuration such that the first and second surfaces do not face each other.

2. The device of claim 1, wherein in the first unfolded configuration, the connector is interposed between the first and second panels when viewed, from a point that is away from the device, in a direction perpendicular to the first surface.

3. The device of claim 1, wherein the connector is further configured to enable the first panel to spontaneously slide relative to the second panel along the axis to either the first or second folded configuration when the device is in a configuration that is between the first folded and second folded configurations.

4. The device of claim 1, wherein the connector is further configured to enable the first panel to spontaneously slide relative to the second panel along the axis to either the first or second unfolded configuration when the device is in a configuration that is between the first unfolded and second unfolded configurations.

5. The device of claim 1, wherein the connector comprises a guide extending along the axis and non-slidably coupled to the second panel, wherein the connector further comprises a slider slidably engaged with the guide and non-slidably coupled to the first panel.

6. The device of claim 5, wherein the guide comprises a first magnet and a second magnet spaced from each other along the axis, wherein the slider comprises a third magnet and a fourth magnet arranged between the first and second magnets along the axis.

7. The device of claim 6, wherein the first magnet and the third magnet are configured to attract each other, and wherein the second magnet and the fourth magnet are configured to attract each other.

8. The device of claim 7, wherein the device is configured to form a third folded configuration that is between the first and second folded configurations, wherein an attractive force between the first and third magnets is greater than an attractive force between the second and fourth magnets when the device is in a configuration that is between the first folded and third folded configurations.

9. The device of claim 8, wherein the guide further comprises a fifth magnet, wherein the slider further comprises a sixth magnet, wherein the fifth magnet and the sixth magnet are arranged such that a repulsive force can be exerted therebetween in a configuration where the device is slightly off the third folded configuration.

10. A method of operating a portable electronic device, the method comprising:
providing the portable electronic device of claim 1;
rotating the first panel relative to the second panel about the axis; and
sliding the first panel relative to the second panel along the axis.

11. The method of claim 10, wherein sliding the first panel relative to the second panel along the axis changes a configuration of the device between the first and second folded configurations.

12. The method of claim 10, wherein sliding the first panel relative to the second panel along the axis changes a configuration of the device between the first and second unfolded configurations.

13. The method of claim 10, wherein rotating the first panel relative to the second panel about the axis changes a configuration of the device between the first folded configuration and the first unfolded configuration.

14. The method of claim 10, wherein rotating the first panel relative to the second panel about the axis changes a configuration of the device between the second folded configuration and the second unfolded configuration.

15. The method of claim 10, wherein the connector enables the first panel to spontaneously slide relative to the second panel along the axis to either the first or second folded configuration when the device is in a configuration that is between the first folded and second folded configurations.

16. The method of claim 10, wherein the connector enables the first panel to spontaneously slide relative to the second panel along the axis to either the first or second unfolded configuration when the device is in a configuration that is between the first unfolded and second unfolded configurations.

17. A portable electronic device, comprising:
a first panel comprising a first surface;
a second panel comprising a second surface, wherein the first surface and the second surface are of substantially the same size;
a connector interconnecting the first panel and the second panel, wherein the connector is configured to rotatably connect the first panel and the second panel relative to each other about an axis and further configured to slidably connect the first panel and the second panel relative to each other along the axis;
wherein the device is configured to form a first folded configuration in which the first surface faces the second surface and the first surface substantially entirely overlaps with the second surface;
wherein the device is further configured to form a second folded configuration in which the first surface faces the second surface, and the first and second panels are linearly offset along the axis from the first folded configuration such that the first surface partially overlaps with the second surface;
wherein the device is further configured to form a first unfolded configuration in which the first and second panels are angularly offset about the axis from the first folded configuration such that the first and second surfaces do not face each other; and
wherein the first panel comprises a display screen on the first surface, wherein the connector does not overlap with the display screen in the first folded configuration when viewed, from a point that is away from the first surface, in a direction perpendicular to the first surface.

18. The device of claim 17, wherein the connector is interposed between the first and second panels when viewed, from a point that is away from the device, in a direction perpendicular to the first surface.

19. The device of claim 17, wherein the first panel comprises a third surface facing away from the second surface in the first folded configuration, wherein the first panel comprises a second display screen on the third surface, wherein the second display screen does not overlap with the connector in the first folded configuration when viewed, from the point that away from the first surface, in a direction perpendicular to the first surface.

20. The device of claim 17, wherein the second panel comprises an array of buttons on the second surface, wherein the array of buttons does not overlap with the connector in the first folded configuration when viewed, from a point that is away from the second surface, in a direction perpendicular to the second surface.

21. The device of claim 17, wherein the connector comprises a hinge configured to enable the first panel to rotate relative to the connector about the axis.

22. The device of claim 17, wherein the connector comprises a guide extending along the axis and non-slidably coupled to the first panel, wherein the connector further comprises a slider slidably engaged with the guide and non-slidably coupled to the second panel.
